(19) United States
(12) Patent Application Publication
(10) Pub. No.: US 2024/0098936 A1
(43) Pub. Date: Mar. 21, 2024

(54) MICROTEXTURES FOR THIN-FILM EVAPORATION

(71) Applicant: INDIAN INSTITUTE OF TECHNOLOGY ROPAR, Rupnagar (IN)

(72) Inventors: Chander Shekhar SHARMA, Rupnagar (IN); Anand S, Rupnagar (IN)

(73) Assignee: INDIAN INSTITUTE OF TECHNOLOGY ROPAR, Rupnagar (IN)

(21) Appl. No.: 18/229,950

(22) Filed: Aug. 3, 2023

(30) Foreign Application Priority Data
Sep. 13, 2022 (IN) 202211052374

(51) Int. Cl. H05K 7/20

(52) U.S. Cl. CPC H05K 7/20309

(57) ABSTRACT

The present invention discloses microtextures for a thin-film evaporation. The microstructure is called as wedged micropillar and a forest of these micropillar helps in maintaining a thin-film of liquid over the heat sink surface through capillary action. The inherent sharp corners of these wedged micropillars drives the liquid filament along the vertical direction and the large mean curvature of the liquid meniscus provides high capillary pumping pressure. At the same time, these microstructures can offer high permeability for liquid flow thereby leading to low viscous pressure loss as compared to the cylindrical microstructured heat sink. As a result of these, the predicted dryout heat flux for thin-film evaporation is more than twice that of the conventional cylindrical microstructures. Also, we have proposed a combined architecture of wedged and cylindrical micropillars for hotspot-targeted cooling application.

### CROSS-REFERENCE TO RELATED APPLICATIONS AND PRIORITY

The present application claims benefit from Indian Patent Application No. 202211052374 filed on 13 Sep. 2022 the entirety of which is hereby incorporated by reference.

### FIELD OF THE INVENTION

The present disclosure generally relates to microtextures for thin-film evaporation. More particularly, the present disclosure relates to thin-film evaporation from microtextured surfaces in order to enhance the performance of various engineering applications.

### BACKGROUND OF THE INVENTION

Evaporation is a ubiquitous phenomenon in the nature as well as employed in comprehensive technological applications namely thermal management of electronics, satellite microthrusters, solar steam generation and water desalination. The realization of thin-film evaporation by the advancement of the microstructured surfaces have provided a direction towards enhancing the thermal performance of the above systems. Even though the metric of performance enhancement for each of these systems could vary, like for example the dryout heat flux in case of electronics cooling or the rate of evaporation in case of the microthruster and steam generation, these demands can be met by the development of innovative microstructures. The field of electronics cooling is taken as a case to disseminate the present invention in its entirety. Thermal management technologies became an inevitable part of the electronics industry from its inception to ensure long-term and reliable operation. There have been numerous innovations in the cooling of microprocessor chips starting from the air to the single-phase liquid to the two-phase liquid cooling. The air-based cooling saw tremendous growth during the past decades but, as the power dissipation increased with the demand for high computing performances over the years, the forced air cooling started getting stretched towards its extreme limit. The lower specific heat capacity of air, bulky and heavier assembly, increased noise as well as the power consumption of the fans used makes the air cooling system inferior in managing the high heat flux loads. The single phase liquid cooling techniques offered a wide range of opportunity towards enhancing the performance of the microelectronics systems. Emergence of new generation of processors with improved capability demanded higher cooling requirements which the forced convection liquid systems cannot meet sustainably. So, the industry looked forward for phase change based liquid cooling techniques in order to take advantage of its large latent heat of vaporization. Nowadays it is common to see two phase heat transfer devices such as heat pipes and vapour chambers used extensively in thermal management of high heat flux dissipating circuits, especially for mobile devices such as smartphones and laptops. Other techniques like the flow boiling, spray and jet impingement are broadly researched with limited application in the practical devices due to their inherent stability issues.

The basic method to address the heat dissipation from any device is by providing an air-based (forced convection) cooling system. This system encompasses a fan on top of the heat sink which is mounted on the source of heat generation. The poor thermophysical properties of air, bulky and heavier assembly, increased noise as well as the power consumption of the fans are the major shortfalls of the air cooling system. The emergence of applications that generates more data, and its subsequent processing requires processors of high computational power. The power dissipation of these high-performance processor chips is escalating to such a limit that the air-based cooling techniques cannot maintain the junction temperature below the designed operating temperature limit. So, here we propose a cooling method based on the phase change heat transfer wherein the latent heat of vaporization of the liquid (water) is utilized to manage the high heat flux dissipation from the source.

Although, there have been strategies on enhancing the air cooling system by designing efficient fans and air movers, optimization of heat sinks, and improving the overall thermal resistance but these become less feasible as the power density rises with the newer generation of microprocessors. It is always preferred to have cooling systems that consume minimal energy compared to the total energy requirement of the electronic system. Similarly, the single-phase liquid cooling methods have been explored and studied jointly with various types of heat sinks such as micro pin fins, manifold microchannel, and conventional micro and mini channels with inherent limitation pertaining to the high pumping power. Hence, the proposed system addresses this limitation of forced convection cooling by focusing on the passive nature of liquid transport through microstructures by capillary pumping.

The two-phase cooling encompasses commonly the flow and the pool boiling methods that demonstrates remarkable thermal performance, however it is accompanied by flow and bubble dynamics instabilities as well as dependence on the orientation. Also, the technologies like spray and jet impingement cooling shows promising performance but needs to overcome the issues such as gravity dependence and flow obstruction. The current innovation addresses the above shortcomings by inculcating the capillary-fed thin-film evaporation for dissipating high heat flux.

The above described technologies are also not feasible for mobile computers such as smartphones and laptops. For thermal management of such products, thin-film evaporation based heat transfer devices, such as vapor chambers and heat pipes, are used. These heat transfer devices can operate until dryout of the liquid contained inside, after which the devices cannot transfer the heat from microelectronics, thus leading to its failure.

Capillary driven thin-film evaporation is a promising mechanism by virtue of which high power density components can be operated within the specified limit by utilizing the latent heat of the liquid. The operation of the thin-film evaporation heat sink with cylindrical micropillars is depicted in FIG. 1, where the liquid is driven from the reservoir to the microtextured surface due to the capillary force exerted at the contact line along the wall of pillars. As seen, the meniscus curvature changes in the flow direction (away from the reservoir) due to the evaporation and the liquid pressure within the wick is governed by the Young-Laplace equation. For a given combination of substrate and liquid (here silicon oxide and water), the receding contact angle is nearly 15 degree. When the applied heat flux equals to the dryout heat flux, the curvature of the meniscus in the last unit cell attains the maximum and the corresponding contact angle is the receding contact angle. Further increase of the applied heat flux does not change the contact angle (curvature) but depins the contact line from the pillar top edge, leading to dryout of the liquid, as shown at the rightmost end of micropillar array in FIG. 1.

Hence, the dryout heat flux refers to the maximum heat flux beyond which dry patches start to appear within the microstructures along with sudden spike in the wick surface temperature. The primary reason for dryout is the dominance of the viscous force in comparison to the capillary force due to which the reservoir is unable to supply the liquid to the entire length of the microstructured wick. The meniscus which is formed within the microstructures is classified into three regions as depicted in the FIG. 2 viz. adsorbed layer or non-evaporating region, thin-film or transition region, and meniscus or bulk fluid region.

The non-evaporating region is characterized by very thin (few nanometers) uniform layer of liquid with strong adhesive forces. The thin-film region is of the order of a few microns in thickness along with a gradient in the curvature. In the meniscus region the curvature becomes constant and acts as the source of liquid supply for the other two regions. With regard to the heat transfer performance, the region II has the least overall thermal resistance due to its low film thickness and intermolecular forces. On the other hand, both the region I and III have the highest thermal resistance because of the strong intermolecular force of attraction and high conduction resistance through the thick liquid film respectively.

Cylindrical micropillars of different orientations have been explored both numerically and experimentally as the microstructure for thin-film evaporation in numerous studies. The maximum dryout heat flux achievable was limited by the viscous pressure drop. So, new strategies are required to increase evaporation while limiting viscous pressure drop penalty. Wick structures with corner rise established by the near-zero radii of contact formed between the abutting cylinders has also been demonstrated. These can achieve higher evaporation but these structures are in the macroscale and cannot be utilized as part of heat sink as flow gets obstructed by the abutting structures.

Hence, increasing the thin-film region of the liquid meniscus and minimizing the viscous losses for liquid transport are the two necessary factors for enhancing the dryout heat flux of the thin-film evaporation. Also, enhancing the thin-film region through the microtexturing can be instrumental for improving the performance of various thermal systems like the solar steam generation, desalination of water and propulsion systems for small satellites.

### OBJECTS OF THE INVENTION

Main object of the present disclosure is to provide a microstructure of micropillars for thin-film evaporation.

Yet another object of the present disclosure is to provide a wedged micropillar with different number of wedges on the periphery along the axis of the micropillar for significantly enhanced capillary-fed thin-film evaporation.

Another object of the present disclosure is to provide a microstructure for a thin-film evaporation heat sink to thermally manage high heat flux dissipation from microelectronics.

Yet another object of the present disclosure is to provide a combined architecture of wedged and cylindrical micropillars based heat sink for hotspot-targeted cooling.

### SUMMARY OF THE INVENTION

Before the present microtextures for thin-film evaporation in heat sink is described, it is to be understood that this application is not limited to a particular microtextures system for thin-film evaporation in heat sink as there may be multiple possible embodiments, which are not expressly illustrated in the present disclosures. It is also to be understood that the terminology used in the description is for the purpose of describing the particular implementations, versions, or embodiments only, and is not intended to limit the scope of the present application. This summary is provided to introduce aspects related to microtextures for thin-film evaporation with an emphasis on the thermal management application. This summary is not intended to identify essential features of the claimed subject matter nor is it intended for use in determining or limiting the scope of the claimed subject matter.

The present invention discloses microtexture for thin-film evaporation. The microtexture is called as wedged micropillar and a forest of these micropillar helps in maintaining a thin-film of liquid over the heat sink surface through capillary action. The inherent sharp corners of these wedge micropillars drives the liquid filament along the vertical direction and the large mean curvature of the liquid meniscus provides high capillary pumping pressure. At the same time, these microtextures offer high permeability for liquid flow thereby leading to low viscous pressure loss as compared to the cylindrical microstructured heat sink. Thus the predicted dryout heat flux for thin-film evaporation is more than twice that of the conventional cylindrical microstructures. Also, in another embodiment a combined architecture of wedge and cylindrical micropillars for hotspot-targeted cooling application is proposed.

### STATEMENT OF INVENTION

Accordingly, the present invention discloses microtextures (1) for thin film evaporation comprising plurality of micropillars (2) configured from at least one predetermined profile for maintaining a thin-film of liquid over a surface through capillary action and a micropillar (2) configured with at least one wedge (6, 7, 9, 10) on the periphery along the axis of the micropillar (2).

The number of wedges are configured to be selected based on the requirement of the dryout heat flux and retention of thin film evaporation. The micropillars (2) are configured to provide an extended thin filament (4) of liquid along the corners of the wedged micropillar (6, 7) for enhanced evaporation performance. The wedged micropillars (6, 7) are configured to be positioned at the location of a hotspot for optimal hotspot cooling and the low heat flux background zones are configured with cylindrical micropillars (5). The microtexture (1) is configured with cylindrical micropillars (5), wedged micropillars (6, 7) with varying number of wedges, and hybrid micropillars (9) to reduce the pressure drop for flow of liquid through the microtexture (1). The microtextures (1) are configured for capillary-fed thin-film evaporation. At least one wedge micropillar is configured to be formed from one or plurality of wedges to form a polygonal structure. The micropillar (2) with wedges is configured from a constant corner angle along height of the said micropillar (6, 7). The said micropillar (2) with wedges is configured from varying corner angle along the height of the said micropillar (10) for further increasing the rise of the liquid along the corner.

### BRIEF DESCRIPTION OF DRAWINGS

The foregoing detailed description of embodiments is better understood when read in conjunction with the appended drawings. For the purpose of illustrating the present subject matter, an example of construction of the present subject matter is provided as figures; however, the present subject matter is not limited to the specific microtextures for thin-film evaporation disclosed in the document and the figures.

The present subject matter is described in detail with reference to the accompanying figures.

FIG. 1 illustrates a front view of the 1D conventional cylindrical micropillar array during thin film evaporation.

FIG. 2 illustrates a schematic diagram showing three regions of an evaporating meniscus formed at the contact line.

FIG. 3 illustrates a schematic diagram showing an Isometric view of (a) the cylindrical micropillar (b) four-wedge micropillar; (c) six-wedge micropillar.

FIG. 4 shows a schematic diagram illustrating an equilibrium meniscus shape of liquid generated from Surface Evolver for the forest of four-wedge micropillar heat sink.

FIG. 5 illustrates a schematic diagram showing an Isometric and front views of the meniscus shape for (a) Cylindrical; (b) four-wedge; (c) six-wedge micropillars.

FIG. 6 illustrates a schematic diagram showing a thin-film region highlighted by hatching for wedged micropillar.

FIG. 7 illustrates a chart showing a Thin-film area fraction for cylindrical, four and six wedge micropillar.

FIG. 8 illustrates a chart showing a Viscous pressure drop for cylindrical, four and six wedge micropillar.

FIG. 9 illustrates a chart showing a Figure of Merit for cylindrical, four and six wedge micropillar.

FIG. 10 illustrates a chart showing a predicted dryout heat flux for cylindrical, four and six wedge micropillar.

FIG. 11 shows a schematic representation illustrating a top view of combined architecture of cylindrical and wedge micropillars for a hotspot-targeted heat sink.

FIG. 12 shows a schematic representation illustrating a top view of combined architecture of cylindrical, hybrid and four-wedge micropillars for a hotspot-targeted heat sink.

FIG. 13 shows a schematic representation illustrating a top view of combined architecture of cylindrical, hybrid, four-wedge and six-wedge micropillars for a hotspot-targeted heat sink.

FIG. 14 illustrates a schematic diagram showing an Isometric view of (a) four-wedge micropillar; (b) six-wedge micropillar, with varying corner angle α along the height.

FIG. 15 illustrates a schematic diagram showing an Isometric view of hybrid micropillar with (a) one-wedge; (b) two-wedge, along the circumference.

FIG. 16 illustrates the side and top view SEM images of the microfabricated (a) cylindrical; (b) six-wedge, micropillar array

### DETAILED DESCRIPTION

Some embodiments of this disclosure, illustrating all its features, will now be discussed in detail. The words “comprising,” “having,” “containing,” and “including,” and other forms thereof, are intended to be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise. Although any microtextures for thin-film evaporation and, similar or equivalent to those described herein may be used in the practice or testing of embodiments of the present disclosure, the exemplary, microtextures for thin-film evaporation in heat sink is now described.

Various modifications to the embodiment will be readily apparent to those skilled in the art and the generic principles herein may be applied to other embodiments. However, one of ordinary skill in the art will readily recognize that the present disclosure is not intended to be limited to the embodiments described but is to be accorded the widest scope consist in this regard, in a generic sense.

Researchers have ventured into other geometries of microstructure (1) for achieving enhanced thermal performance for various technological applications. The present application introduces a microstructure (1) geometry with a novel design which can significantly enhance the thin-film evaporation performance of the heat sinks in order to thermally manage high heat flux dissipation from microelectronics.

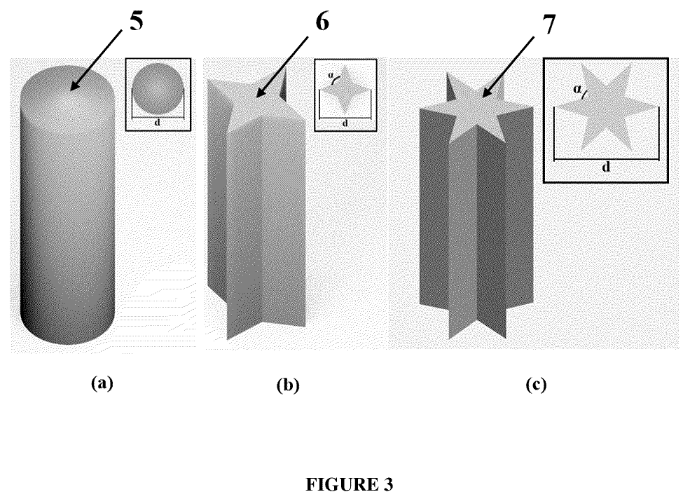

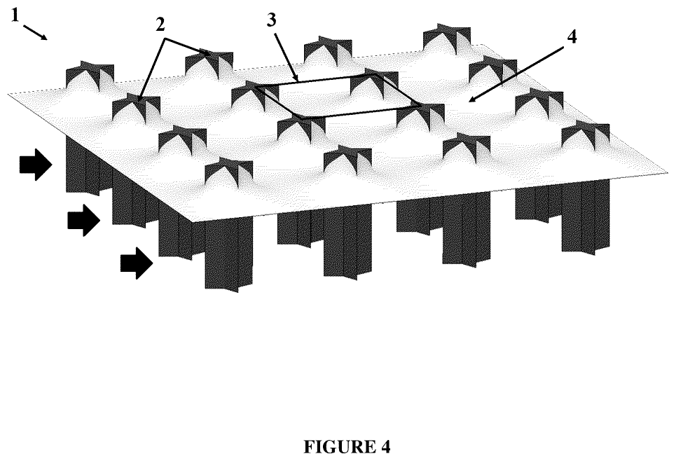

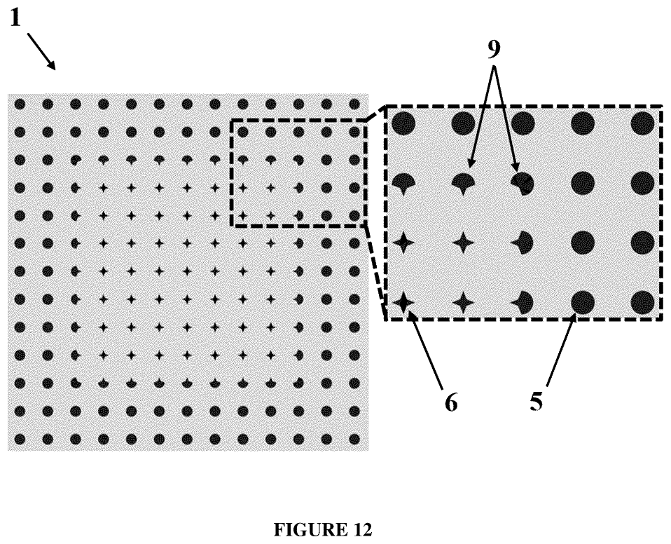

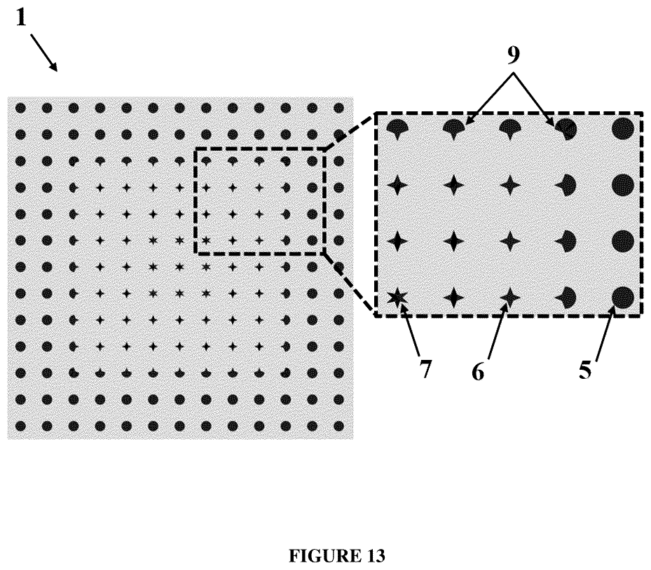

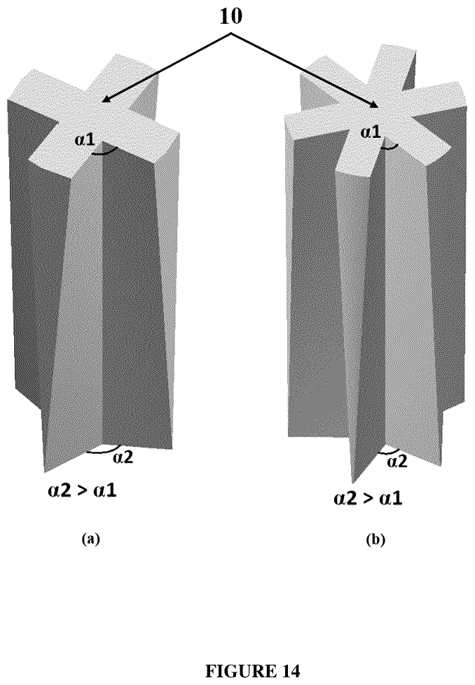

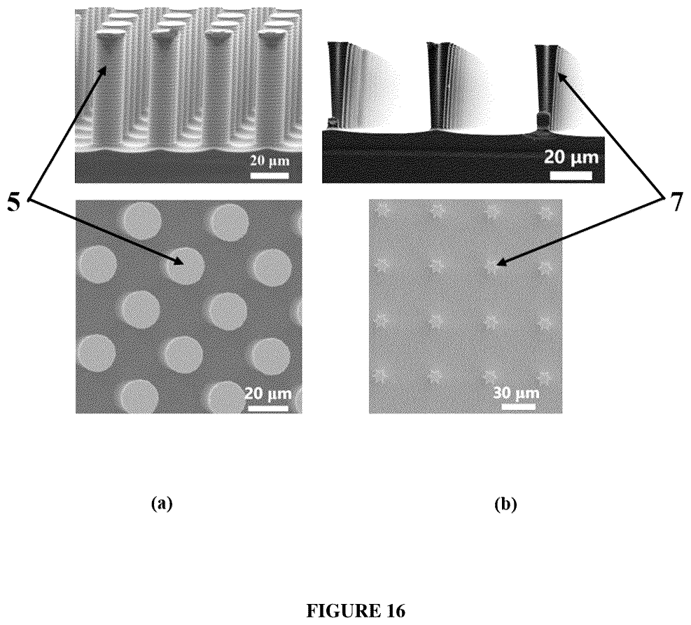

The present subject matter discloses a novel capillary-fed thin-film evaporation heat sink. The proposed design is engineered to incorporate corners in micropillars (2) to be used for thin film evaporation. FIGS. 3b and 3c shows two embodiments of the proposed designs of micropillar (6, 7) having the wedge corner angle α. However, the other embodiments of the micropillar (2) will also comprise of hybrid micropillars (9) wherein wedges are incorporated along only a fraction of the periphery (FIGS. 12 and 13). In one of the embodiment shown, the corner angle α is constant along the height. According to another embodiment this corner angle α can be varied along the height as shown in FIGS. 14a and 14b, depending on ease of fabrication of the structures, to further increase the liquid rise along the corner. The selection of the corner angle and thereby the number of wedges is based on the Concus-Finn criteria which states that the liquid rise along the corner is spontaneous and unbounded when the sum of half corner angle (α/2) and contact angle (Θ) is less than 90 degree. The number of wedges along the periphery can be chosen based on the performance requirement. For brevity, two variants of the wedged micropillar (6, 7) geometry are illustrated in the FIGS. 3b and 3c. The corner angle α for the cases shown in FIGS. 14a and 14b is also chosen based on the Concus-Finn criteria wherein the angle decreases from bottom to top. Our objective is to develop a heat sink with forest of wedge micropillar (6, 7) (FIG. 4) to maintain a thin film of liquid through capillarity and at the same time provide an extended thin filament (4) of liquid along the corners of the wedge micropillar (6, 7) for enhanced evaporation performance. The geometric parameters of the novel microstructure are the nominal diameter (d), pitch (l), height (h), corner angle α, and number of wedges around the periphery of the micropillar (2). And these parameters can be optimized based on the available fabrication process to maximize the dryout heat flux. For the purpose of demonstrating the enhancement in performance, we have shown the comparison of results for two embodiments of wedged micropillars (6, 7) with cylindrical micropillars (5) of d=20 μm, 1=50 μm, and h=50 μm. The material of the microstructure (1) can be any material with good thermal conductivity and suitability to available fabrication processes such as metals or semiconductors. The SEM images of cylindrical (5) and six-wedge micropillar (7) arrays, microfabricated through etching in Silicon, by the method of deep reactive ion etching (DRIE) is illustrated in FIGS. 16a and 16b.

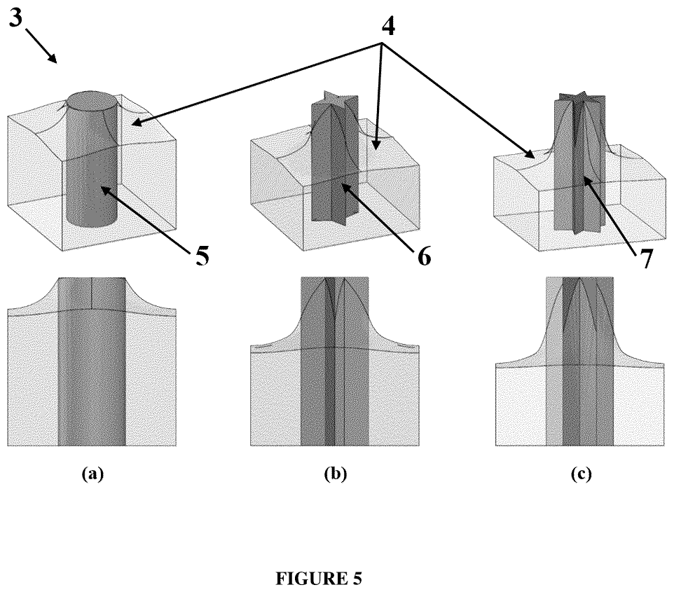

The initial step in the design methodology is the generation of the equilibrium liquid meniscus (4) shape which is developed through an energy minimization approach implemented with the help of Surface Evolver. The comparison of meniscus shape for cylinder (5), four (6), and six-wedge micropillars (7) is depicted in FIG. 5, where the wedged micropillars (6, 7) have an extended thin-film region demonstrated by the high corner filament rise.

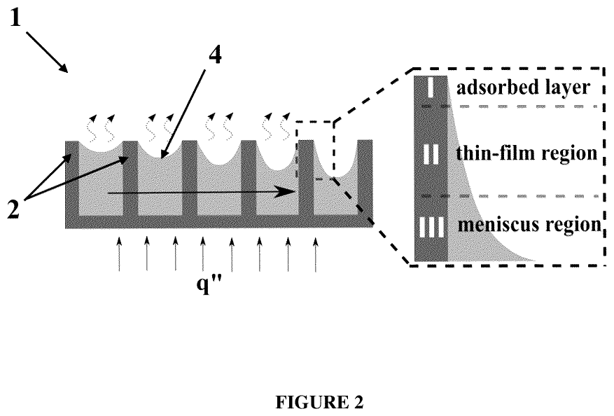

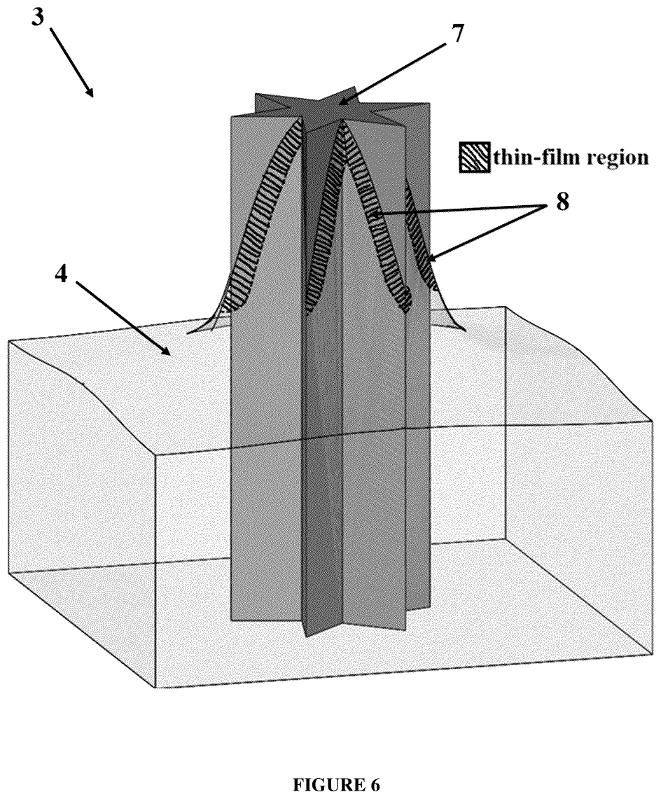

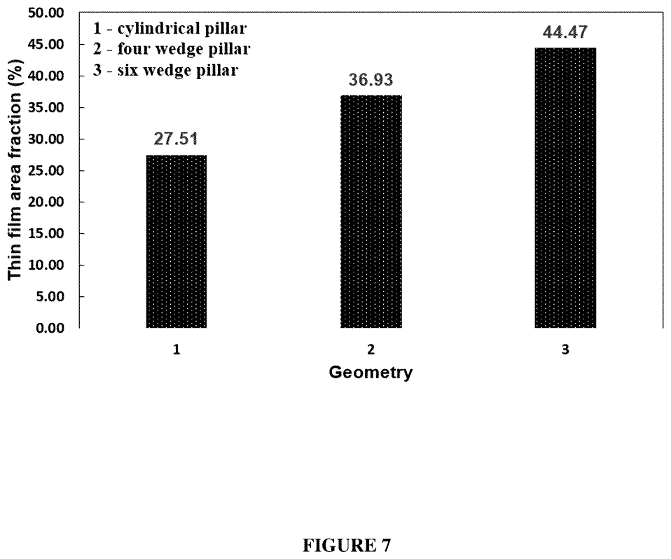

It has been observed that most of the evaporation occurs from the thin-film region (8) (Region II in FIG. 2, also highlighted by hatching in FIG. 6 for a wedge micropillar) where the liquid film thickness is in the range of 1-10 microns. Hence, we characterized various micropillar (2) geometry on the metric of Thin Film Area fraction (TFA) as shown in FIG. 7 which is the ratio of the surface area of the liquid meniscus (4) within the thin-film region (8) to that of the projected area of the unit cell. Compared to the conventional cylindrical micropillar (5), the four (6) and six-wedge micropillar (7) provides an enhancement of 34% and 62% respectively for the TFA. This result states that the significant improvement in the thin-film region (8) of the wedged micropillar (6, 7) provides an opportunity for a higher rate of evaporation thereby dissipating high heat flux from the microprocessors.

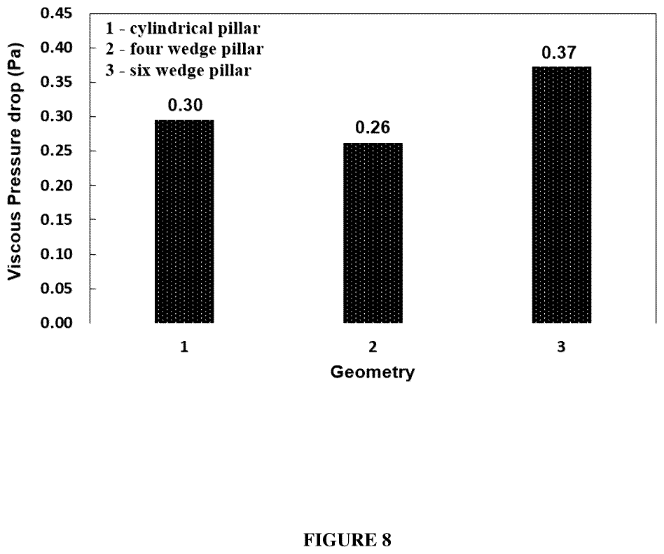

The second metric upon which the wedged micropillars (6, 7) are characterized is the viscous pressure drop for flow of liquid through the microtexture (1). FIG. 8 shows the comparison of this viscous pressure drop of all the cases considered in this work. The viscous pressure drop has been obtained for a given mass flow rate condition corresponding to a heat flux of 100 W/cm². The minimum and maximum pressure loss are observed for the four (6) and six-wedge micropillars (7) respectively.

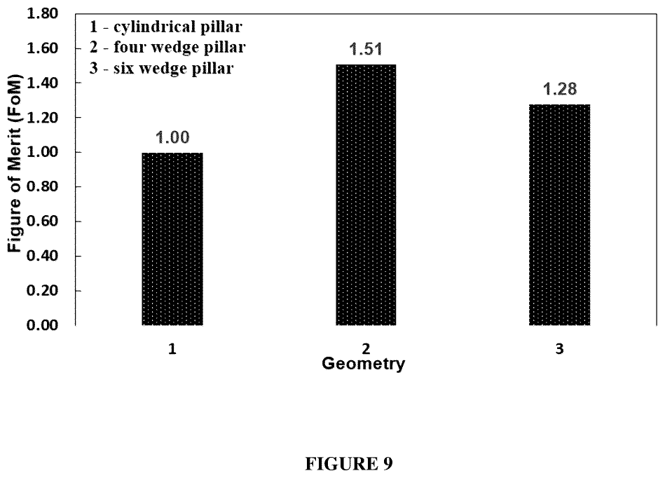

In order to determine an overall comparison of the microstructures (1), we defined a third metric known as the Figure of Merit (FoM) (equation 1) which compares the increase in TFA with viscous pressure drop penalty, relative to the control case of cylindrical micropillar (5) as shown in FIG. 9.

$$F o M = \frac{\frac{T F {A}_{i}}{T F {A}_{0}}}{\frac{Δ {P}_{i}}{Δ {P}_{0}}} \qquad 1$$

The two wedged micropillar (6, 7) geometries achieve significantly higher FoM values compared to the conventional cylindrical (5) geometry which clearly indicates a potential to achieve higher dryout heat flux. The four-wedge micropillar (6) shows the highest FoM due to its minimal pressure drop. The six-wedge micropillar (7) maintains a large thin-film region (8) and hence achieves a better FoM than the conventional cylindrical micropillar (5), despite incurring a higher pressure drop.

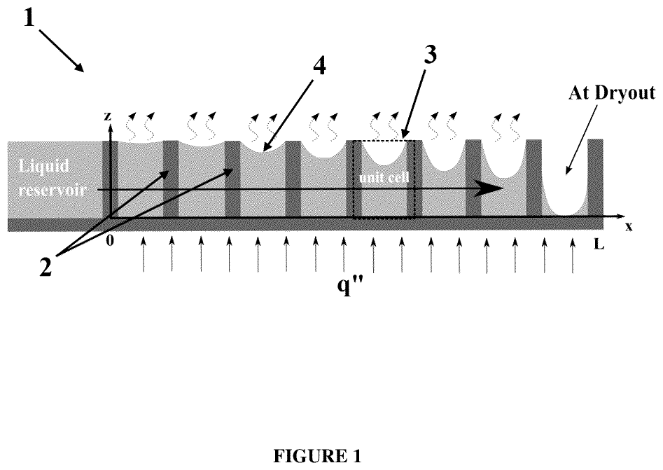

Next, we estimate the dryout heat flux for thin-film evaporators based on these three exemplar geometries by using a validated numerical model. In this model, the micropillar (2) array is discretized into unit cells (3) as depicted in FIG. 1. Fluid flow CFD simulation is implemented in each unit cells (3) to obtain the velocity distribution corresponding to the applied pressure gradients. The unit cells (3) are coupled together by the conservation of mass and enthalpy (equation 2) to compute the distribution of meniscus curvature and liquid pressure

Mⁱ⁻¹−Mⁱ=\dot{m}l²

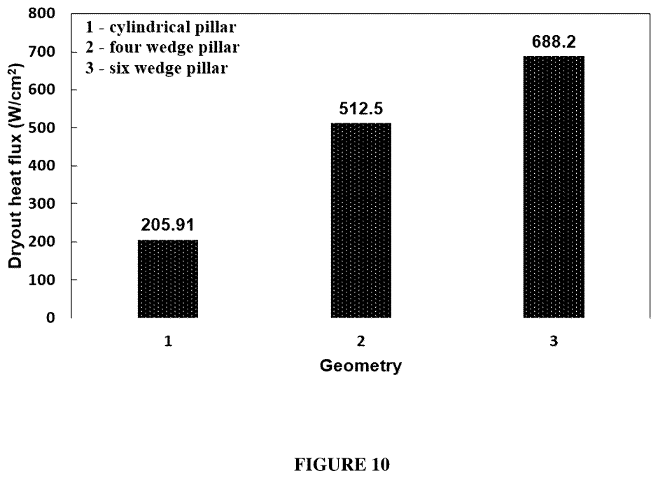

(Mⁱ⁻¹−Mⁱ)hₗ−\dot{m}l²hᵥ+l²qᵢₙ=0 2

where Mⁱ is the mass flow rate at the mid plane of i^{th} unit cell (3), \dot{m} is the rate of mass evaporated per unit area, hₗ and hᵥ represent liquid and vapour enthalpy respectively, and qᵢₙ is the input heat flux to each cell. The initial boundary condition is assumed such that the inlet of the evaporator wick is supplied by the reservoir with a flat liquid-vapour interface with a liquid mass flow rate equivalent to the mass evaporated from the entire evaporator length. The enthalpy balance equation is solved in an iterative manner to ascertain the input heat flux that corresponds to the dryout based on the receding criteria as elaborated earlier. The dryout heat flux predicted based on this numerical model for both cylindrical (5) and two wedged micropillar (6, 7) based heat sink of wicking length L=5 mm is as shown in FIG. 10. It is clearly evident that both four and six-wedge micropillar (7) based heat sinks are capable of dissipating much higher heat flux through thin-film evaporation (more than 148% and 234% respectively) compared to the cylindrical (5) microstructure heat sink. The high thermal performance of the proposed microstructure (1) is due to the extended thin-film region (8) of the liquid meniscus (4), increased liquid/vapour interfacial mean curvature leading to improved capillary pumping, and the high permeability for liquid flow through the wedged (6, 7) microstructures.

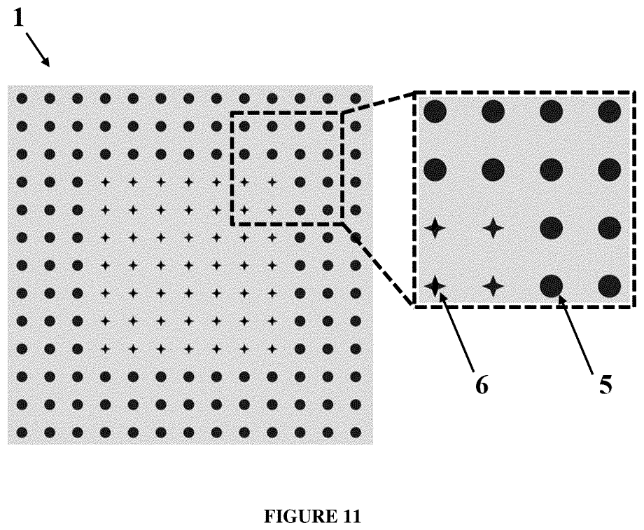

In another embodiment a combined architecture of cylindrical (5) and wedged micropillar (6, 7) heat sink for hotspot-targeted cooling is illustrated. The micropillars (2) can be arranged according to the size and position of the hotspots, to meet the cooling requirement. A case is illustrated in FIG. 11 wherein the wedged micropillars (6, 7) may be positioned at the location of a hotspot (center) and the low heat flux background zones will be housing the cylindrical micropillars (5).

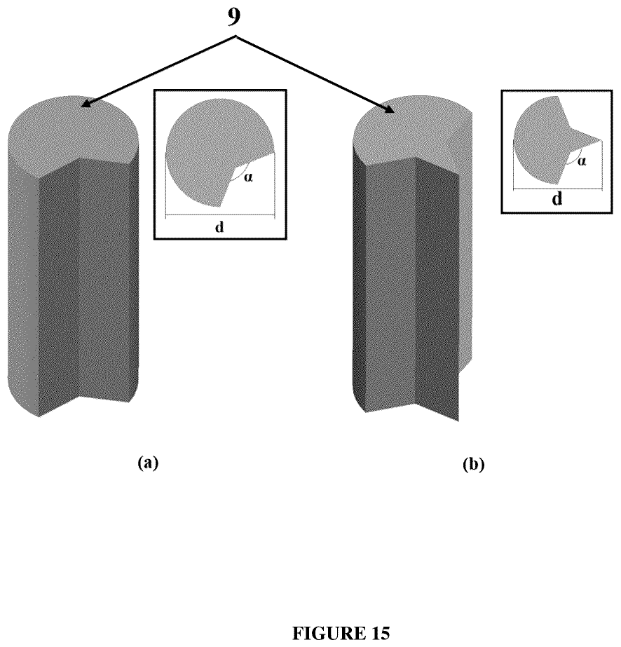

In another embodiment a possible architecture to reduce the pressure drop is depicted in FIGS. 12 and 13. It consists of combination of cylindrical (5), wedged (6, 7), and hybrid micropillars (9) (i.e. micropillars wherein wedges are incorporated along only a fraction of the circumference). The cylindrical micropillars (5) are placed in outer background zones, wedged micropillars (6, 7) at the location of hotspots, and hybrid micropillars (9) are placed in the transition zone. Two variants of hybrid micropillars (9) are illustrated in FIGS. 15a and 15b that are used in the transition zone. FIG. 12 shows a design wherein four-wedge micropillars (6) are placed in the hotspot zone. FIG. 13 shows a design wherein both four (6) and six-wedge micropillars (7) are used in the hotspot zone. Such a combined design can be tuned in terms of pillar locations according to the heat flux map of the microelectronics device to be cooled.

In essence, microtextures (1) for thin film evaporation comprising of micropillars (2) with different number of wedges can be configured based on the requirement of the dryout heat flux and retention of thin film evaporation. The micropillars (2) are configured to provide an extended thin filament (4) of liquid along the corners of the wedged micropillar (6, 7) for enhanced evaporation performance. The wedged micropillars (6, 7) are configured to be positioned at the location of a hotspot for optimal hotspot cooling and the low heat flux background zones are configured with cylindrical micropillars (5). The microtexture (1) is configured with cylindrical micropillars (5), wedged micropillars (6, 7) with varying number of wedges, and hybrid micropillars (9) to reduce the pressure drop for flow of liquid through the microtexture (1). The microtextures (1) are configured for capillary-fed thin-film evaporation. At least one wedge micropillar is configured to be formed from one or plurality of wedges to form a polygonal structure. The micropillar (2) with wedges is configured from a constant corner angle along height of the said micropillar (6, 7). The said micropillar with wedges is configured from varying corner angle along the height of the said micropillar (10) for further increasing the rise of the liquid along the corner

Exemplary embodiments discussed above may provide certain advantages. Though not required to practice aspects of the disclosure, these advantages may include the following:

Some embodiments of the present subject matter provide a microstructure (1) of micropillars (2) for a heat sink.

Some embodiments of the present subject matter provide a wedged micropillar (6, 7) with different number of wedges on the periphery along the axis of the micropillar (2) for significant enhanced capillary-fed thin-film evaporation.

Some embodiments of the present subject matter provide a microstructure (1) for a thin-film evaporation heat sink to thermally manage high heat flux dissipation from microelectronics.

Some embodiments of the present subject matter provide a combined architecture of wedged (6, 7, 9) and cylindrical micropillars (5) based heat sink for hotspot-targeted cooling.

Although implementations for microtextures (1) for thin-film evaporation in heat sink have been described in language specific to structural features and/or system, it is to be understood that the appended claims are not necessarily limited to the specific features as described. Rather, the specific features are disclosed as examples of implementations.

FIGS. 1-16 are now described using the reference numbers stated in the below table.

| Reference Numeral | Description |
|---|---|
| 1 | Microstructures/Microtextures |
| 2 | Micropillar |
| 3 | Unit cell |
| 4 | Liquid meniscus/filament |
| 5 | Cylindrical micropillar |
| 6 | Four-wedge micropillar |
| 7 | Six-wedge micropillar |
| 8 | Thin-film region |
| 9 | Hybrid micropillar |
| 10 | Varying corner angle wedged micropillar |

1. Microtextures for thin film evaporation comprising:
plurality of micropillars configured from at least one predetermined profile for maintaining a thin-film of liquid over a surface through capillary action; and
a micropillar configured with at least one wedge on the periphery along the axis of the micropillar.

2. Microtextures for thin film evaporation as claimed in claim 1, wherein the number of wedges are configured to be selected based on the requirement of the dryout heat flux and retention of thin film evaporation.

3. Microtextures for thin film evaporation as claimed in claim 1, wherein said micropillars are configured to provide an extended thin filament of liquid along the corners of the wedged micropillar for enhanced evaporation performance.

4. Microtextures for thin film evaporation as claimed in claim 1, wherein the wedged micropillars are configured to be positioned at the location of a hotspot for optimal hotspot cooling and the low heat flux background zones are configured with cylindrical micropillars.

5. Microtextures for thin film evaporation as claimed in claim 1, wherein said microtexture is configured with cylindrical micropillars, wedged micropillars with varying number of wedges, and hybrid micropillars to reduce the pressure drop for flow of liquid through the microtexture.

6. Microtextures for thin film evaporation as claimed in claim 1, wherein said microtextures are configured for capillary-fed thin-film evaporation.

7. Microtextures for thin film evaporation as claimed in claim 1, wherein said at least one wedge micropillar is configured to be formed from one or plurality of wedges to form a polygonal structure.

8. Microtextures for thin film evaporation as claimed in claim 1, wherein said micropillar with wedges is configured from a constant corner angle along height of the said micropillar.

9. Microtextures for thin film evaporation as claimed in claim 1, wherein said micropillar with wedges is configured from varying corner angle along the height of the said micropillar for further increasing the rise of the liquid along the corner.
